(19) United States
(12) Patent Application Publication
(10) Pub. No.: US 2005/0067216 A1
(43) Pub. Date: Mar. 31, 2005

(54) Waterproof patient handset

(76) Inventors: Werner Schuhmann, Munchen (DE); Johann Hien, Munchen (DE)

Correspondence Address: IP LEGAL DEPARTMENT;TYCO FIRE & SECURITY SERVICES, ONE TOWN CENTER ROAD, BOCA RATON, FL, 33486, US

(21) Appl. No.: 10/675,204

(22) Filed: Sep. 30, 2003

(51) Int. Cl. H05K 5/00

(52) U.S. Cl. 181/149

(57) ABSTRACT

A present waterproof patient handset includes a speaker contained within an enclosure. The enclosure has a number of holes sufficient to allow sound to pass from the speaker through the enclosure. A foil is placed on the enclosure over the holes, and attached to the enclosure only at the foil's perimeter such that the remainder of the foil acts as a second membrane for the speaker. At the same time, the foil seals the speaker against intrusion by a liquid. A protection plate with holes sits between the enclosure and the speaker, and provides mechanical protection for the speaker. A rear cover has at least one boss having at least one deformable rib. The boss is inserted through a hole in a printed circuit board (PCB). The rib is deformed when the PCB is pressed with the front cover against the rib.

### BACKGROUND

Nurse call and communication systems have been developed to meet the requirements of hospitals, nursing homes, retirement homes and service housing areas, and penal institutions such as prisons and forensic clinics.

Patient handsets are used to provide an assortment of control functions for different call activities, lighting and external systems (blinds, TV, radio), as well as audio functions.

### SUMMARY OF THE INVENTION

To provide patients and nurses with a high level of comfort and hygiene, it is preferable to be able to wash a patient handset without the concern of water or other washing liquids entering the handset. A patient handset for nurse call use in hospitals must be very easy to clean. Cleaning is easiest if the handset is waterproof. This is particularly difficult where audio is provided, as a major problem lies in sealing a standard speaker, while allowing the sound to radiate without major attenuation.

In addition, a printed circuit board (PCB) must fit between a back (rear) and a front cover of the patient handset housing. While the handset must be sealed, for cost purposes, it is undesirable to use screws to fix the PCB on the front cover. At the same time, the tolerance in thickness of the PCB must be eliminated, especially if small buttons are used.

Finally, it is important to prevent the speaker from being damaged or destroyed mechanically.

In at least one embodiment of the present invention, the speaker is sealed by gluing a round foil, such as 0.1 mm or 0.2 mm polyester, onto the molding behind which the speaker is placed. The foil is glued, for example, only at the 2-3 mm outside perimeter of the foil, so that it can act as a second membrane/diaphragm for the speaker. The rear cover molding under the foil has about 30 1 mm holes to allow the sound generated by the speaker to pass to the foil.

A magnetic shield, sitting between the rear cover molding and the speaker, provides mechanical protection for the speaker. In one embodiment, the magnetic shielding has holes similar to those in the rear cover molding; however, the holes are skewed, or offset, relative to those of the rear cover so that a foreign object entering a hole in the rear cover cannot damage the speaker.

In one embodiment of the present invention, the rear cover of the handset has five ribbed bosses that pass through holes of the PCB. The ribs are relatively weak, i.e., deformable. The PCB is pressed with the front cover against the boss ribs. The PCB deforms the ribs until the front cover fits on the boss. Thus, the thickness of the PCB is factored out without using screws to fix the PCB to the front cover.

According to an embodiment of the present invention, a waterproof patient handset includes a speaker contained within an enclosure. The enclosure has a number of holes, e.g., about thirty holes, having a diameter of about 1 mm, sufficient to allow sound to pass from the speaker through the enclosure. A foil is placed on the enclosure over the holes, and attached to the enclosure only at the foil's perimeter, e.g., the outer 2 or 3 mm, such that the remainder of the foil (the unattached or unglued part) acts as a second membrane for the speaker. At the same time, the foil seals the speaker against intrusion by a liquid such as water.

A protection plate which sits between the enclosure and the speaker, provides mechanical protection for the speaker. Preferably, the protection plate also has a number of holes that allow the passage of sound. The holes are preferably offset from the holes in the enclosure. The protection plate may also serve as a magnetic shield.

In at least one embodiment, the enclosure includes a first cover and a second cover, for example, a front cover and a back or rear cover. The second cover has at least one boss having a deformable rib. The boss is inserted through a hole in a printed circuit board (PCB) to be mounted within the enclosure. The rib is deformed when the PCB is pressed with the first cover against the rib.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1 is a side cutaway view of a portion of the handset of an embodiment of the present invention.

FIG. 2 is an illustration of a magnetic shield used in the embodiment of FIG. 1.

FIG. 3 is an illustration of the foil used to seal the speaker of FIG. 1.

FIG. 4A is a side cutaway view of the full handset of FIG. 1.

FIG. 4B is a side cutaway view of a portion of the handset of FIG. 4A.

FIG. 5 is a mechanical drawing of an inside view of the rear cover of the embodiment of FIGS. 1, 4A and 4B.

FIGS. 6A and 6B are mechanical drawings of, respectively, a top view and side view of a boss of FIG. 5.

FIG. 6C is a mechanical drawing illustrating the deformity to the ribs of a rear cover boss.

FIGS. 7A-7D are drawings that illustrate various embodiments of the handset of the present invention.

### DETAILED DESCRIPTION OF THE INVENTION

A description of preferred embodiments of the invention follows.

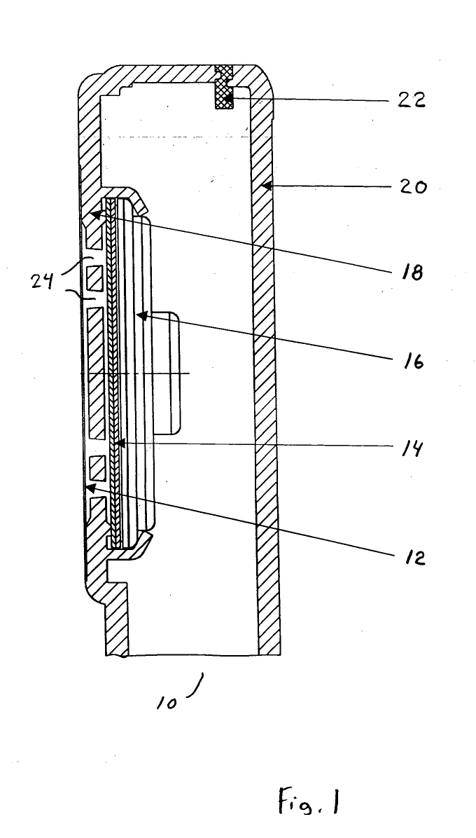

FIG. 1 is a side cutaway view of a portion of the handset 10 of an embodiment of the present invention. The handset case consists of a front cover 20 and a rear cover 18. The case is generally made waterproof by a sealing gasket 22 placed between the front cover 20 and the rear cover 18.

A speaker 16 is housed within the casing, in this embodiment mounted to the rear cover 18. The rear cover 18 has a series of holes 24 over the speaker 16 to allow sound generated by the speaker 16 to pass through the rear cover 18 substantially unattenuated. A foil 12 is glued to the rear cover 18 over the speaker 16. The foil observes to keep water out of the handset 10, while at the same time acting as a second diaphragm for the speaker 16. A magnetic shield 14 mechanically protects the speaker 16 against foreign objects should the foil 12 be pierced.

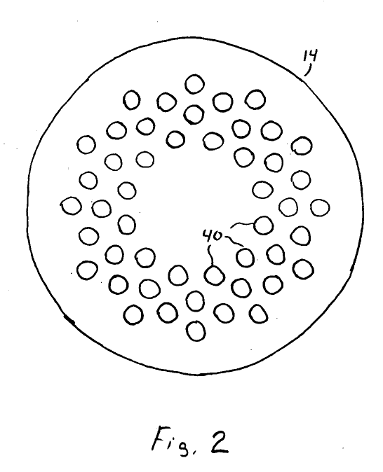

FIG. 2 is an illustration of a magnetic shield 14 that could be used in the embodiment of FIG. 1. Like the rear cover 18 (FIG. 1), the magnetic shield 14 has a series of holes 40 that allow sound generated by the speaker 16 to pass through. These holes 40 are preferably skewed relative to the holes 24 in the rear cover 18. One skilled in the art would readily recognize that other hole patterns or sizes could also be effective. In one embodiment, the magnetic shield 14 is made, for example, from two pieces of Electroband DIN46400/1-V530-50a 0.5 mm.

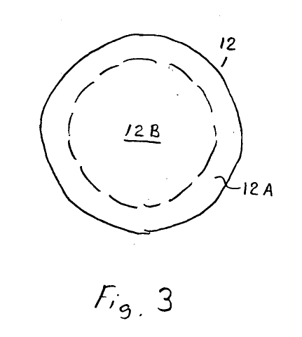

FIG. 3 is an illustration of the foil 12 used to seal the speaker 16 (FIG. 1). In the embodiment shown, the annular region 12A, bounded by the dashed line and the outside edge, is glued to the rear cover 18, thus further waterproofing the handset 10. The remainder of the foil (the part inside the dashed line, designated 12B) is not glued and is free to vibrate, thus acting as a second diaphragm for the speaker 16.

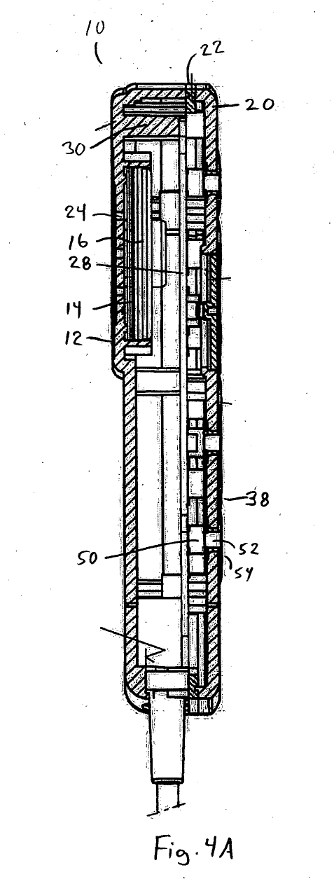

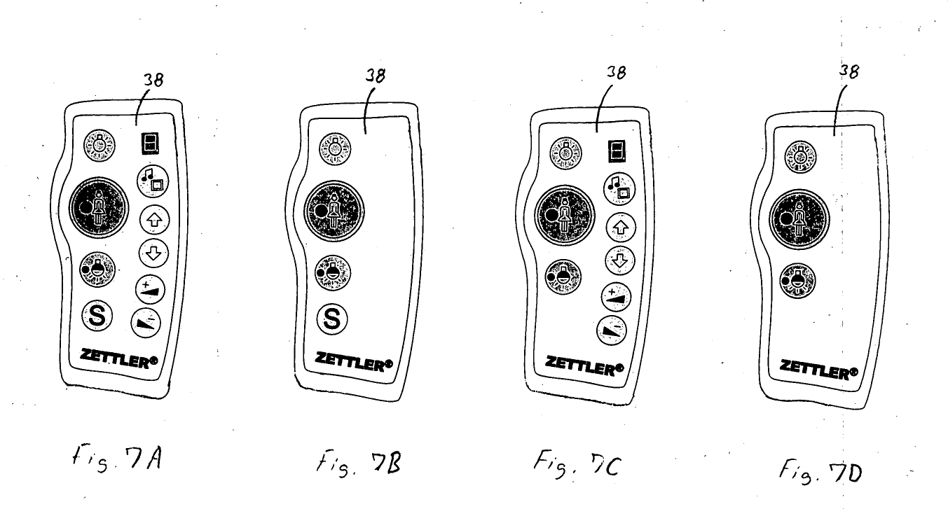

FIG. 4A is a side cutaway view of the full handset 10 of FIG. 1, illustrating another aspect of the invention. A membrane 38 (not shown in FIG. 1) is glued to and covers most of the front cover 20 and provides functional indications 54 to a user. (See FIGS. 7A-7E.) One or more functional switches 50 mounted on a printed circuit board 28 are located such that the respective actuators 52 lie just under the indications 54 of the membrane 38.

FIG. 4B is a side cutaway view of a portion of the handset of FIG. 4A. It is critical for proper operation that the distance D from the top of the circuit board 28 to the front cover be tightly controlled. However, generally, the thickness of a printed circuit board is not sufficiently controlled and could vary, for example, depending on the vendor, the specific material, the batch, etc. For example, if the distance D is excessive, a user may not be able to activate a switch. On the other hand, if the distance D is too small, excessive wear and tear on the membrane 38 may cause damage to the membrane 38 or the switch.

Therefore, an embodiment of the present invention uses ribbed bosses 30 to which screws 26 are attached to hold the printed circuit board 28 within the case, while at the same time holding the case together without allowing the thickness of the printed circuit board 28 to have any effect on the distance D. The boss 30 is inserted through a hole in the printed circuit board 28, which rests against the tops of the ribs 32, which do not extend the full length of the boss 30. As the screw 26 is tightened through the front cover 20 into the boss 30, the tops of the ribs 30 are deformed by the printed circuit board 28 until a front cover boss 48 is flush against the rear cover boss 30. The deformity is shown at 34. Note how, upon screwing screw 26 into the rear cover boss 30, the front cover boss 48 forces the printed circuit board 28 towards the rear cover 18, deforming the ribs at 34, until the front cover boss 48 makes contact with the rear cover boss 30, assuring that the distance D between the top of the printed circuit board 28 and the front cover 20 is within allowable margins.

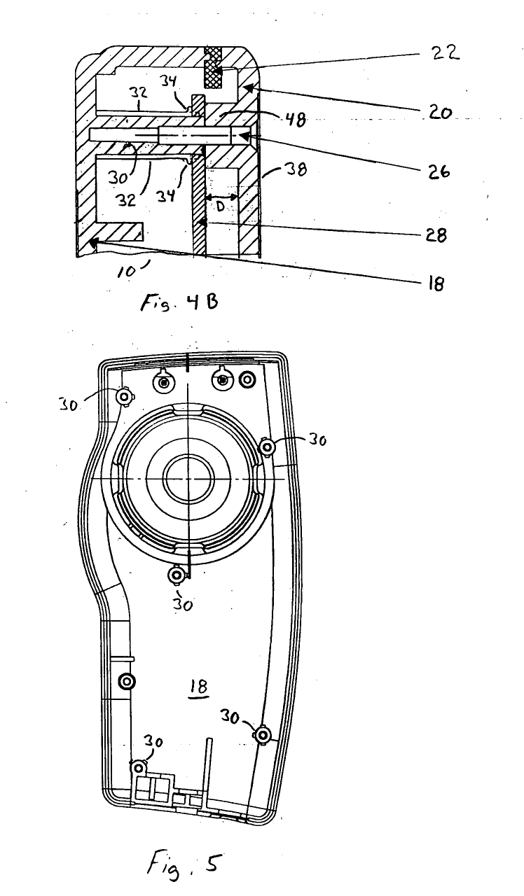

FIG. 5 is a mechanical drawing of an inside view of the rear cover 18 of the embodiment of FIGS. 1, 4A and 4B. This particular embodiment has five ribbed bosses 30 on which to support the printed circuit 28 (FIG. 4B). Although each of the bosses 30 has three ribs as shown, one skilled in the art would readily recognize that different numbers of ribs, e.g., two or four, could also be effective, and that even within a single unit, different bosses could have different numbers of ribs.

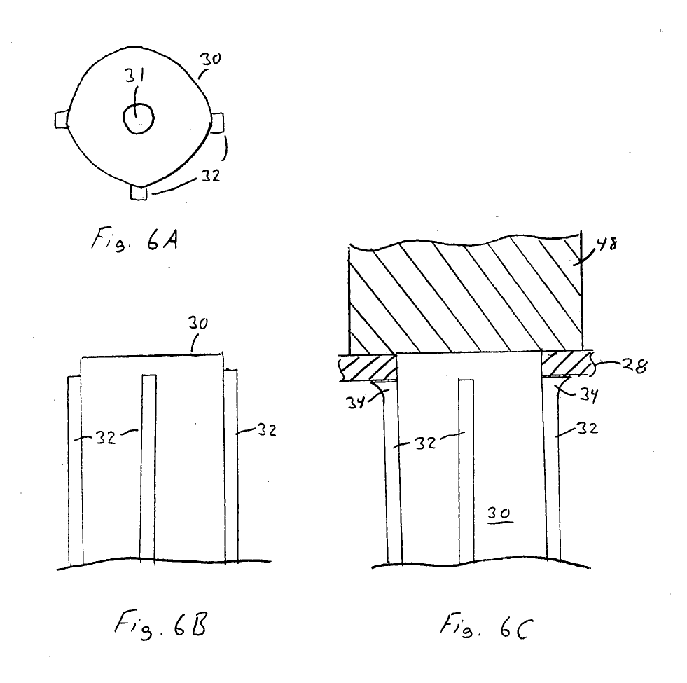

FIGS. 6A and 6B are mechanical drawings (not to scale) of, respectively, a top view and side view of a boss 30 of FIG. 5. A hole 31 which receives a screw 26 is visible on the top view of FIG. 6A. FIG. 6C is a mechanical drawing illustrating the deformity 34 to the ribs 32 of a rear cover boss 30 that results from the force applied by the front cover boss 48 on the printed circuit board 28.

FIGS. 7A-7D are drawings that illustrate various embodiments of the handset of the present invention. Different features and functional buttons are available on the different models, as indicated by the membranes 38.

While this invention has been particularly shown and described with references to preferred embodiments thereof, it will be understood by those skilled in the art that various changes in form and details may be made therein without departing from the scope of the invention encompassed by the appended claims. For example, while the above description indicates that the holes in the cover and in the protective plate are round, they may also be elongated slot, or other regular or irregular shapes.

1. A waterproof patient handset, comprising:
an enclosure;
a speaker contained within the enclosure, the enclosure comprising a plurality of holes sufficient to allow sound to pass from the speaker through the enclosure; and
a foil placed on the enclosure over the holes, and attached to the enclosure at the foil's perimeter such that the foil seals the speaker against intrusion by a liquid.

2. The handset of claim 1, the foil acting as a second membrane for the speaker.

3. The handset of claim 1, the foil being round and being glued only at about the outer 2 to 3 mm of the foil.

4. The handset of claim 1, the enclosure having about thirty of said holes, each hole having a diameter of about 1 mm.

5. The handset of claim 1, further comprising:
a protection plate which sits between the enclosure and the speaker, providing mechanical protection for the speaker, the protection plate comprising a plurality of holes which allow the passage of sound, said holes being offset from the holes in the enclosure.

6. The handset of claim 5, the protection plate also serving as a magnetic shield.

7. The handset of claim 1, the enclosure comprising a first cover and a second cover, the second cover having at least one boss which is inserted through a hole in a printed circuit board (PCB), the boss having a deformable rib.

8. The handset of claim 7, the PCB deforming the rib when the PCB is pressed with the first cover against the rib.

9. A waterproof patient handset, comprising:
an enclosure;
a speaker contained within the enclosure, the enclosure comprising a plurality of holes sufficient to allow sound to pass from the speaker through the enclosure;
a foil placed on the enclosure over the holes, and attached to the enclosure at the foil's perimeter such that the foil acts as a second membrane for the speaker, the foil sealing the speaker against intrusion by a liquid; and
a magnetic shield located between the enclosure and the speaker, providing mechanical protection for the speaker, the magnetic shield comprising a plurality of holes which allow the passage of sound, said holes being offset from the holes in the enclosure.

10. The waterproof patient handset of claim 9, the enclosure comprising a first cover and a second cover, and the second cover having at least one boss which is inserted through a hole of a printed circuit board (PCB), said boss having at least one deformable rib which is deformed when the PCB is pressed with the first cover against the rib, until the first cover meets the boss.

11. A waterproof patient handset, comprising:
enclosure means;
audio means contained within the enclosure means, the enclosure means allowing sound to pass from the audio means through the enclosure means;
waterproofing means placed on the enclosure means, said waterproofing means acting as a second membrane for the audio means; and
protection means located between the enclosure means and the audio means, providing mechanical protection for the audio means and allowing passage of sound from the audio means to the waterproofing means.

12. The waterproof patient handset of claim 11, the enclosure means comprising a front cover and a back cover, the back cover having fastening means which are deformed when a printed circuit board (PCB) is pressed with the front cover, the front cover being fastened to the back cover using said fastening means, the PCB being installed therein, such that the distance between a top surface of the PCB and the front cover is within a certain margin of error regardless of the PCB's thickness.

13. A method for waterproofing a patient handset, comprising:
enclosing a speaker within the handset;
providing a plurality of holes in the handset enclosure sufficient to allow sound to pass from the speaker through the enclosure; and
placing a foil on the enclosure over the holes by attaching the foil to the enclosure at the foil's perimeter such that the foil acts as a second membrane for the speaker, the foil sealing the speaker against intrusion by a liquid.
